(19) United States
(12) Patent Application Publication
(10) Pub. No.: US 2026/0280538 A1
(43) Pub. Date: Sep. 17, 2026

(54) CLOCK TRANSMISSION DEVICE AND OPERATION METHOD THEREOF

(71) Applicant: MACRONIX International Co., Ltd., Hsinchu (TW)

(72) Inventors: Tung-Yu Li, Taoyuan City (TW); Shang-Chi Yang, Changhua County (TW); Hsuan-Chieh Lin, Kaohsiung City (TW)

(73) Assignee: MACRONIX International Co., Ltd., Hsinchu (TW)

(21) Appl. No.: 19/075,792

(22) Filed: Mar. 11, 2025

(51) Int. Cl. H03K 5/1252; G06F 1/08; H03G 3/30; H03K 17/56

(52) U.S. Cl. CPC H03K 5/1252; G06F 1/08; H03G 3/30; H03K 17/56

(57) ABSTRACT

A clock transmission device and an operation method thereof are provided. The clock transmission device may be applied to a three-dimensional NAND flash memory with high capacity and high performance. The clock transmission device includes a clock transmission circuit and a jitter suppression circuit. The clock transmission circuit generates an output clock based on an input clock. The jitter suppression circuit supplies a power current to the clock transmission circuit based on a power voltage. The jitter suppression circuit adaptively adjusts the power current in response to a power supply noise of the power voltage to suppress the power noise induced jitter of the output clock.

### BACKGROUND

### Technical Field

The disclosure relates to a memory device, and in particular to a clock transmission device and an operation method thereof.

### Description of Related Art

Memory integrated circuits including three-dimensional NAND flash memory (3D NAND flash memory) with high capacity and high performance are continuously evolving. To address the issue of size reduction, the NAND flash memory industry has transitioned from planar architecture to 3D architecture. The storage capacity of 3D vertical NAND flash memory has continuously increased over the past decade to meet the demands of various industries, including mobile and data centers. The increase in the number of stacked word-line (WL) layers plays a critical role in achieving higher storage capacity or bit density. This paradigm shift allows for increased storage density through the vertical stacking of storage cells, instead of solely relying on cell miniaturization. Charge-trap technology uses a continuous silicon nitride layer as the storage node (SN). Compared to floating gate technology, charge-trap technology is widely used in 3D NAND flash memory arrays due to simpler process and higher vertical scaling capability.

The interface circuit in memory integrated circuits may transfer data between internal circuits and external circuits. However, power noise causes jitter on both the data DQ path and the strobe clock DQS path. If the data DQ and strobe clock DQS are matched, the power noise jitter on the DQ and DQS paths is the same. Thus, the strobe clock DQS may strobe the center of the data DQ eye diagram. Based on this, the data valid window is maintained.

The Open NAND Flash Interface (ONFI) 5.1 specification provides unmatched DQ and DQS options, allowing the data DQ and strobe clock DQS to no longer track each other. Since the strobe clock DQS path (such as the clock tree distribution) is longer, the strobe clock DQS is more affected by power noise induced jitter (PNIJ). Eliminating the PNIJ of the strobe clock DQS to maintain the data valid window under large power supply noise has become one of the key technical issues in the field of 3D NAND flash memory.

### SUMMARY

The disclosure provides a clock transmission device and an operation method thereof for suppressing a power noise induced jitter (PNIJ) of an output clock.

In an embodiment of the disclosure, a clock transmission device includes a clock transmission circuit and a jitter suppression circuit. The clock transmission circuit generates at least one output clock based on an input clock. The jitter suppression circuit supplies a power current to the clock transmission circuit based on a power voltage. The jitter suppression circuit adaptively adjusts the power current in response to a power supply noise of the power voltage to suppress a PNIJ of the at least one output clock.

In an embodiment of the disclosure, an operation method includes the following steps. At least one output clock is generated based on an input clock by a clock transmission circuit of a clock transmission device. A power current is supplied to the clock transmission circuit based on a power voltage by a jitter suppression circuit of the clock transmission device. The power current is adaptively adjusted by the jitter suppression circuit in response to a power supply noise of the power voltage to suppress a PNIJ of the at least one output clock.

Based on the above, the jitter suppression circuit in the embodiments of the disclosure may detect power supply noise components of the power voltage and dynamically adjust the power current of the clock transmission circuit based on the power supply noise components. For example, when the power supply noise causes an increase in the power voltage, the jitter suppression circuit adaptively decreases the power current of the clock transmission circuit. When the power supply noise causes a decrease in the power voltage, the jitter suppression circuit adaptively increases the power current of the clock transmission circuit. Therefore, the jitter suppression circuit adaptively suppresses the PNIJ of the output clock of the clock transmission circuit in response to the power supply noise of the power voltage.

To make the features and advantages of the disclosure more comprehensible, several embodiments accompanied with drawings are described in detail as follows.

### BRIEF DESCRIPTION OF THE DRAWINGS

FIG. 1 is a circuit block diagram of a non-volatile memory integrated circuit according to an embodiment of the disclosure.

FIG. 2 is a circuit block diagram of a non-volatile memory integrated circuit according to an embodiment of the disclosure.

FIG. 3 is a circuit block diagram of a clock transmission device as illustrated according to an embodiment of the disclosure.

FIG. 4 is a circuit block diagram of a clock transmission device according to an embodiment of the disclosure.

FIG. 5 is a flow diagram of an operation method of a clock transmission device according to an embodiment of the disclosure.

FIG. 6 is a circuit block diagram of a clock transmission device according to another embodiment of the disclosure.

FIG. 7 is a circuit block diagram of a clock transmission circuit as illustrated according to an embodiment of the disclosure.

FIG. 8 is a circuit block diagram of a jitter suppression circuit as illustrated according to an embodiment of the disclosure.

FIG. 9 is a circuit block diagram of a compensation circuit as illustrated according to another embodiment of the disclosure.

FIG. 10 is a circuit block diagram of a noise amplification circuit as illustrated according to an embodiment of the disclosure.

FIG. 11 is a circuit diagram of an error amplification circuit as illustrated according to an embodiment of the disclosure.

FIG. 12 is a circuit diagram of an error amplification circuit as illustrated according to another embodiment of the disclosure.

FIG. 13 is a circuit block diagram of a noise amplification circuit as illustrated according to another embodiment of the disclosure.

FIG. 14 is a circuit diagram of a gain circuit as illustrated according to an embodiment of the disclosure.

FIG. 15 is a circuit diagram of a gain circuit as illustrated according to another embodiment of the disclosure.

FIG. 16 is a circuit diagram of a gain circuit as illustrated according to yet another embodiment of the disclosure.

FIG. 17 is a circuit diagram of a gain circuit as illustrated according to still another embodiment of the disclosure.

FIG. 18 is a circuit block diagram of a noise amplification circuit as illustrated according to yet another embodiment of the disclosure.

### DESCRIPTION OF THE EMBODIMENTS

In this specification (including the claims), the term “coupled to (or connected to)” may refer to any direct or indirect connection method. For example, if it is described that a first device is coupled to (or connected to) a second device, it should be interpreted that the first device may be directly connected to the second device, or the first device may be indirectly connected to the second device through other devices or some connection means. The terms “first,” “second,” and the like mentioned in this specification (including the claims) are used to name components or distinguish between different embodiments or scopes, and they are not intended to limit the upper or lower quantity of components or restrict the sequence of components. Additionally, where applicable, components/elements/steps with the same reference numerals in the figures and embodiments represent the same or similar parts. Components/elements/steps with the same reference numerals or terminology in different embodiments may refer to the corresponding descriptions.

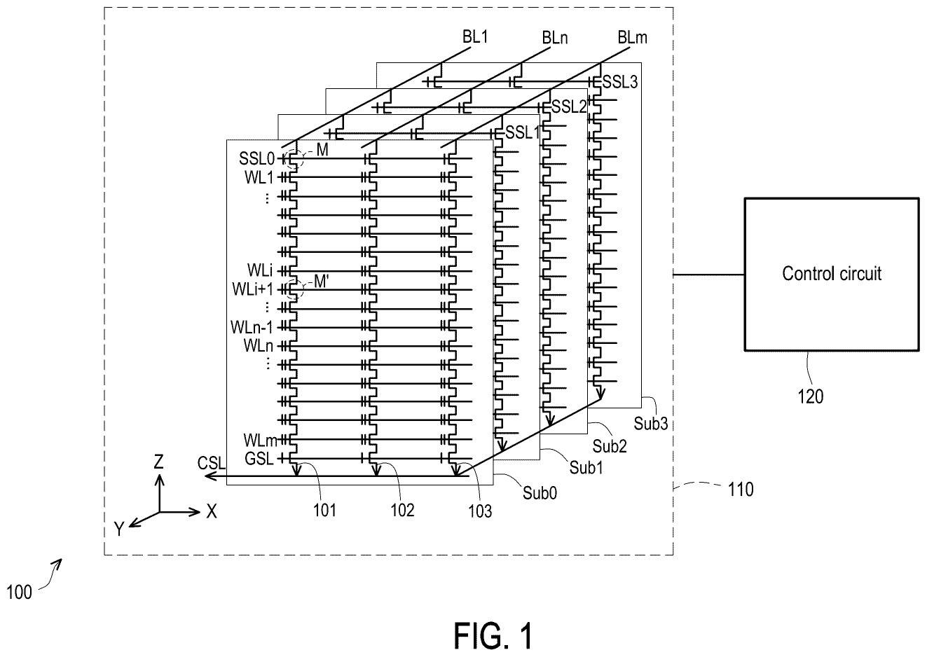

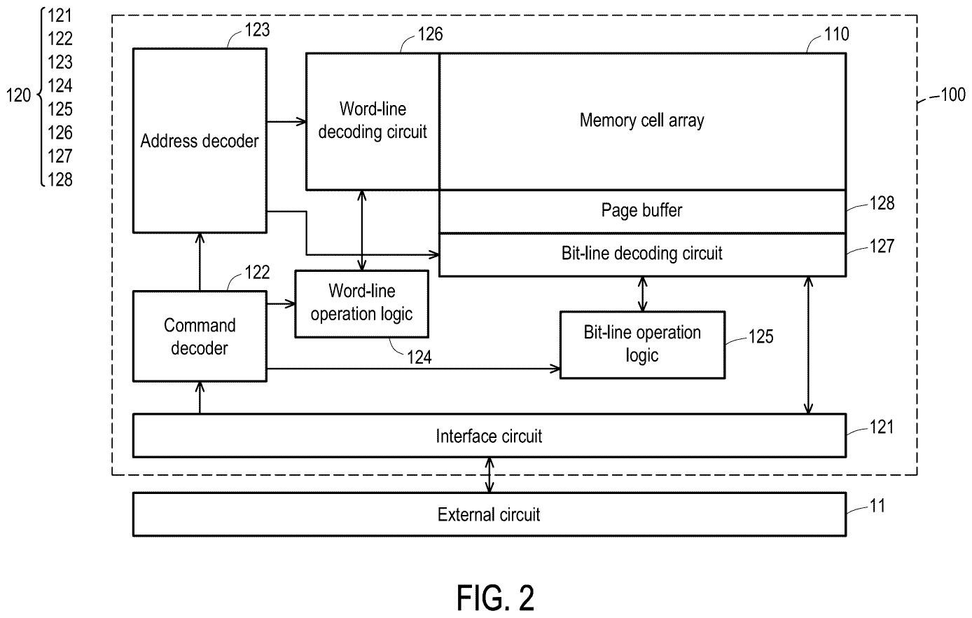

FIG. 1 is a circuit block diagram of a non-volatile memory integrated circuit 100 according to an embodiment of the disclosure. The non-volatile memory integrated circuit 100 includes a memory cell array 110 and a control circuit 120. The control circuit 120 is coupled to the memory cell array 110. The memory cell array 110 shown in FIG. 1 may be one of the many embodiment examples of the memory cell array 110 shown in FIG. 2, and the control circuit 120 shown in FIG. 2 may be one of the many embodiment examples of the control circuit 120 shown in FIG. 1. Depending on different designs, in some embodiments, the control circuit 120 may be implemented as a hardware circuit. In other embodiments, the control circuit 120 may be implemented as a combination of hardware, firmware, and software (i.e., programs).

In terms of hardware, the control circuit 120 may be implemented as logic circuits on an integrated circuit. For example, the relevant functions of the control circuit 120 may be implemented in one or more hardware controllers, microcontrollers, hardware processors, microprocessors, application-specific integrated circuits (ASICs), digital signal processors (DSPs), field-programmable gate arrays (FPGAs), central processing units (CPUs), and/or various logic blocks, modules, and circuits within other processing units. The relevant functions of the control circuit 120 may be implemented as hardware circuits, such as various logic blocks, modules, and circuits in integrated circuits, by using hardware description languages (e.g., Verilog HDL or VHDL) or other suitable programming languages.

In terms of software and/or firmware, the relevant functions of the control circuit 120 may be implemented as programming codes. For example, the control circuit 120 may be implemented using general programming languages (e.g., C, C++, or assembly language) or other suitable programming languages. The programming codes may be recorded/stored in a “non-transitory machine-readable storage medium.” In some embodiments, the non-transitory machine-readable storage medium may include, for example, semiconductor memory and/or storage devices. Electronic devices (e.g., CPUs, hardware controllers, microcontrollers, hardware processors, or microprocessors) may read and execute the programming codes from the non-transitory machine-readable storage medium to achieve the relevant functions of the control circuit 120.

FIG. 1 illustrates an equivalent circuit of a three-dimensional (3D) NAND flash memory integrated circuit in a three-dimensional (3D) arrangement. The memory cell array 110 includes multiple memory cells (e.g., a memory cell M′). The multiple memory cells in the memory cell array 110 shown in FIG. 1 are arranged in a 3D manner within an XYZ coordinate system. However, this does not imply that the circuit of the memory cell array 110 is limited to a 3D arrangement. In an example, the memory cell array 110 may be divided into four sub-blocks Sub0, Sub1, Sub2, and Sub3. The control circuit 120 may independently control the operation of each sub-block (e.g., sub-block Sub0).

Each memory cell string shown in FIG. 1 (e.g., memory cell strings 101, 102, or 103) includes multiple memory cells (e.g., memory cell M′) connected in series along the Z direction. The memory cell array 110 includes multiple word lines (WLs), such as word lines WL1, . . . , WLi, WLi+1, . . . , WLn−1, WLn, . . . , WLm shown in FIG. 1. A word line (e.g., word line WLn) may correspond to a layer in the XY plane. Each word line WL1 to WLm is coupled to multiple memory cells in a corresponding row of the memory cells. The multiple memory cells in each memory cell string (e.g., memory cell string 101) correspond to a word line (e.g., word line WLi+1). A memory cell M may be configured as a string select transistor coupled to a string select line (SSL, e.g., string select lines SSL0, SSL1, SSL2, and SSL3), and another memory cell may be configured as a ground select transistor coupled to a ground select line (GSL). The string select transistor and the ground select transistor are located on opposite sides of each memory cell string (e.g., memory cell string 101). In this example, multiple memory cell strings (e.g., memory cell strings 101, 102, . . . ) coupled to the same string select line (e.g., string select line SSL0) on the same plane (e.g., the plane defined by the X and Z directions) may be defined as a sub-block (e.g., sub-block Sub0).

Multiple bit lines (BLs) are each coupled to multiple memory cells in a corresponding column of the memory cells. That is, each memory cell string (e.g., memory cell strings 101, 102, or 103) is connected to a corresponding bit line (e.g., bit line BL1, BLn, or BLm) through a corresponding string select transistor on the string select line (e.g., string select line SSL0). The memory cell strings in the same column within different sub-blocks (e.g., sub-blocks Sub0, Sub1, . . . ) along the Y direction (e.g., memory cell string 101) are connected to the corresponding bit line (e.g., bit line BL1). The string select line (e.g., string select line SSL0) may be a conductive line or conductive layer formed above the top word-line layer (e.g., word line WL1). Each memory cell string (e.g., memory cell strings 101, 102, or 103) may be connected to a common source line (CSL) through a corresponding ground select transistor on the ground select line GSL. The ground select line GSL may be a conductive line or conductive layer formed below the bottom word-line layer (e.g., word line WLm). The common source line CSL may be a conductive layer formed above the substrate of the non-volatile memory integrated circuit 100. The string select lines (e.g., string select lines SSL0 to SSL3) in the memory cell array 110 may be formed on the same conductive layer but divided into independent lines. Each independent line (string select line) may independently control the operation of the corresponding sub-blocks (e.g., sub-blocks Sub0, Sub1, . . . ) in the memory cell array 110.

In an example, under the single-level cell (SLC) configuration, multiple memory cells (including memory cell M′) within a sub-region (e.g., sub-region Sub0) coupled to the same word line or word-line layer (e.g., word line WLn) may be defined as a page. In another example, under the triple-level cell (TLC) configuration, multiple memory cells (including memory cell M′) within a sub-region (e.g., sub-region Sub0) coupled to the same word line or word-line layer (e.g., word line WLn) may be defined as three pages. In the TLC configuration, the three pages include a high page, a middle page, and a low page. The memory cells M′ on the same word line (e.g., word line WLn) are applied with the same voltage. Each word line (e.g., word line WLn) may be connected to a driver circuit, such as an X-decoder (or a scan driver).

In an example, one or more dummy lines or layers (not shown) may be disposed between the string select lines (e.g., string select lines SSL0 to SSL3) and the word-line layer (e.g., word line WL1), and between the ground select line GSL and the bottom word-line layer (e.g., word line WLm). In another example, one or more dummy lines or layers (not shown) may be disposed in the middle section of each memory cell string (e.g., memory cell strings 101, 102, or 103). The non-volatile memory integrated circuit 100 further includes a control circuit 120, which is used to achieve corresponding operations on the memory cell array 110.

FIG. 2 is a circuit block diagram of a non-volatile memory integrated circuit 100 according to an embodiment of the disclosure. The non-volatile memory integrated circuit 100 shown in FIG. 2 may be referenced based on the related description of FIG. 1. The external circuit 11 sends commands to the non-volatile memory integrated circuit 100 and transmits and receives data from the non-volatile memory integrated circuit 100. Based on the control of the external circuit 11 (e.g., memory controller), the non-volatile memory integrated circuit 100 shown in FIG. 2 provides data access functions to the external circuit 11. In the embodiment shown in FIG. 2, the control circuit 120 includes an interface circuit 121, a command decoder 122, an address decoder 123, a word-line operation logic 124, a bit-line operation logic 125, a word-line decoding circuit 126, a bit-line decoding circuit 127, and a page buffer 128.

The command decoder 122 receives commands (e.g., program commands, read mode commands, write mode commands, etc.) from the external circuit 11 through the interface circuit 121. After receiving the command, the command decoder 122 decodes the command to perform the corresponding operation. For example, the command decoder 122 transmits an array address to the address decoder 123 based on the command decoding result. Under the control of the command decoder 122, the word-line operation logic 124 notifies the word-line decoding circuit 126 of the word line (WL) to be selected and the word line to be deselected. The address decoder 123 decodes the array address and transmits the address decoding result to the word-line decoding circuit 126 and the bit-line decoding circuit 127. Based on the control of the address decoder 123 and the word-line operation logic 124, the word-line decoding circuit 126 selects the corresponding word line of the memory cell array 110.

Under the control of the command decoder 122, the bit-line operation logic 125 notifies the bit-line decoding circuit 127 of the bit line (BL) to be selected and the bit line to be deselected. Under the control of the address decoder 123 and the bit-line operation logic 125, the bit-line decoding circuit 127 transmits and receives data to and from the external circuit 11 through the interface circuit 121. The bit-line decoding circuit 127 selects the corresponding bit line of the memory cell array 110 based on the control of the bit-line operation logic 125. The page buffer 128 includes a sense amplifier, which is used to sense the signal on the bit line to generate corresponding data.

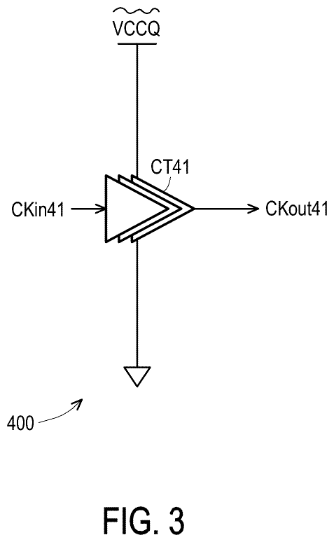

FIG. 3 is a circuit block diagram of a clock transmission device 400 as illustrated according to an embodiment. Based on practical applications, the clock transmission device 400 may be arranged in any functional circuit within any integrated circuit. For example, the clock transmission device 400 may be arranged within the interface circuit 121 of the non-volatile memory integrated circuit 100 shown in FIG. 2. The clock transmission device 400 shown in FIG. 3 includes a clock transmission circuit CT41. The clock transmission circuit CT41 generates an output clock CKout41 based on an input clock CKin41 and provides the output clock CKout41 to the next-stage circuit (not shown). A symbol “VCCQ” shown in FIG. 3 represents a power voltage. Inevitably, the power voltage VCCQ may carry power supply noise. The power supply noise of the power voltage VCCQ will cause jitter in the output clock CKout41, and such jitter is referred to as power noise induced jitter (PNIJ).

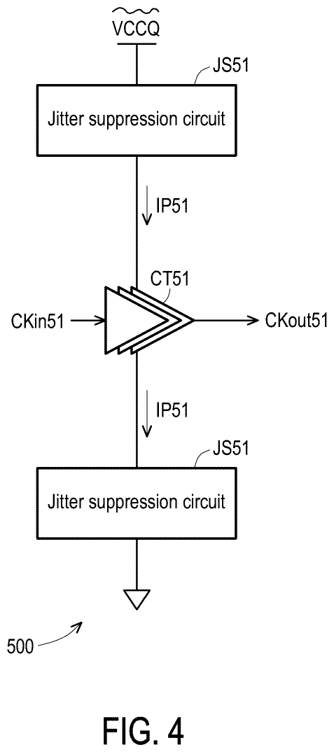

FIG. 4 is a circuit block diagram of a clock transmission device 500 according to an embodiment of the disclosure. Based on practical design and application, the clock transmission device 500 shown in FIG. 4 may be arranged in any functional circuit within any integrated circuit. For example, the clock transmission device 500 may be arranged within the interface circuit 121 of the non-volatile memory integrated circuit 100 shown in FIG. 2 or in other circuits. The clock transmission device 500 shown in FIG. 4 includes a clock transmission circuit CT51 and a jitter suppression circuit JS51. The jitter suppression circuit JS51 is coupled to the power end of the clock transmission circuit CT51. The jitter suppression circuit JS51 may adaptively suppress the PNIJ of the output clock CKout51 in response to the power supply noise of the power voltage VCCQ.

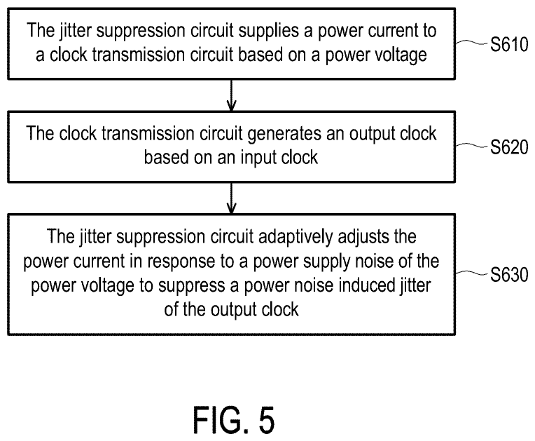

FIG. 5 is a flow diagram of an operation method of a clock transmission device according to an embodiment of the disclosure. Referring to FIG. 4 and FIG. 5, in step S610, the jitter suppression circuit JS51 supplies a power current IP51 to the clock transmission circuit CT51 based on the power voltage VCCQ. In step S620, the clock transmission circuit CT51 generates an output clock CKout51 based on an input clock CKin51 and provides the output clock CKout51 to the next-stage circuit (not shown). In step S630, the jitter suppression circuit JS51 adaptively adjusts the power current IP51 in response to the power supply noise of the power voltage VCCQ to suppress the PNIJ of the output clock CKout51.

In summary, the jitter suppression circuit JS51 may detect the power supply noise components of the power voltage VCCQ and dynamically adjust the power current IP51 of the clock transmission circuit CT51 based on the power supply noise components. For example, when the power supply noise of the power voltage VCCQ causes the power voltage VCCQ to increase, the jitter suppression circuit JS51 adaptively decreases the power current IP51 of the clock transmission circuit CT51. When the power supply noise of the power voltage VCCQ causes the power voltage VCCQ to decrease, the jitter suppression circuit JS51 adaptively increases the power current IP51 of the clock transmission circuit CT51. Therefore, the jitter suppression circuit JS51 may adaptively suppress the PNIJ of the output clock CKout51 of the clock transmission circuit CT51 in response to the power supply noise of the power voltage VCCQ.

In an application scenario where the clock transmission device 500 is applied to the transmission path of the strobe signal DQS, the clock transmission device 500 may suppress the PNIJ of the strobe signal DQS (output clock CKout51). As a result, the strobe signal DQS may strobe the center of the data signal DQ, thereby maintaining the data valid window.

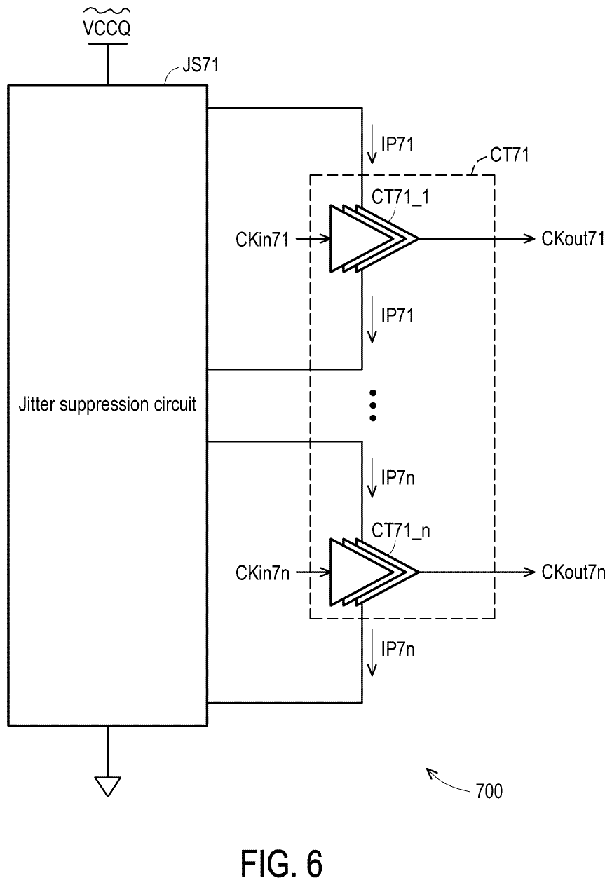

FIG. 6 is a circuit block diagram of a clock transmission device 700 as illustrated according to another embodiment of the disclosure. Based on practical design and application, the clock transmission device 700 shown in FIG. 6 may be arranged in any functional circuit within any integrated circuit. For example, the clock transmission device 700 may be arranged within the interface circuit 121 of the non-volatile memory integrated circuit 100 shown in FIG. 2 or in other circuits. The clock transmission device 700 shown in FIG. 6 includes a clock transmission circuit CT71 and a jitter suppression circuit JS71. The jitter suppression circuit JS71 is coupled to the power end and the reference end of the clock transmission circuit CT71. In the embodiment shown in FIG. 6, the clock transmission circuit CT71 includes multiple clock transmission paths (e.g., n clock transmission paths CT71_1, . . . , CT71_n, where n is an integer). The jitter suppression circuit JS71 is coupled to the power ends and reference ends of the clock transmission paths CT71_1 to CT71_n, as shown in FIG. 6.

The jitter suppression circuit JS71 supplies a power current to the clock transmission circuit CT71 based on the power voltage VCCQ. For example, the jitter suppression circuit JS71 supplies a power current IP71 to the clock transmission path CT71_1 based on the power voltage VCCQ. Similarly, the jitter suppression circuit JS71 supplies a power current IP7n to the clock transmission path CT71_n based on the power voltage VCCQ. The clock transmission circuit CT71 generates different output clocks for the next-stage circuit (not shown) based on multiple input clocks. For example, the clock transmission path CT71_1 generates an output clock CKout71 based on an input clock CKin71. Similarly, the clock transmission path CT71_n generates an output clock CKout7n based on an input clock CKin7n. Any of the clock transmission paths CT71_1 to CT71_n may be referenced to the related description of the clock transmission circuit CT51 shown in FIG. 4 and inferred accordingly. Similarly, the jitter suppression circuit JS71 may be referenced to the related description of the jitter suppression circuit JS51 shown in FIG. 4 and inferred accordingly, so further elaboration is omitted.

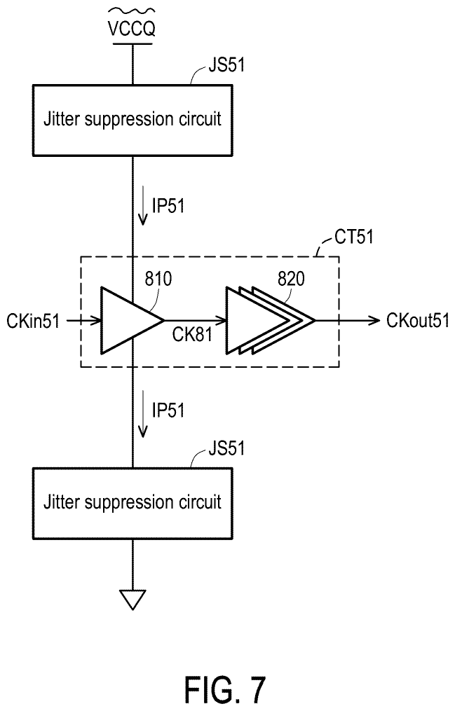

FIG. 7 is a circuit block diagram of the clock transmission circuit CT51 as illustrated according to an embodiment of the disclosure. The clock transmission circuit CT51 shown in FIG. 7 may be one of the many embodiment examples of the clock transmission circuit CT51 shown in FIG. 4. In the embodiment shown in FIG. 7, the clock transmission circuit CT51 includes a gain circuit 810 and a clock tree circuit 820. The jitter suppression circuit JS51 supplies a power current IP51 to the power end of the gain circuit 810 based on the power voltage VCCQ and draws the power current IP51 from the reference end of the gain circuit 810. The gain circuit 810 amplifies the input clock CKin51 to generate a gained clock CK81. The jitter suppression circuit JS51 senses the power supply noise of the power voltage VCCQ to adaptively adjust the power current IP51, thereby suppressing the PNIJ of the gained clock CK81. The clock tree circuit 820 is coupled to the gain circuit 810 to receive the gained clock CK81. The clock tree circuit 820 generates the output clock CKout51 based on the gained clock CK81.

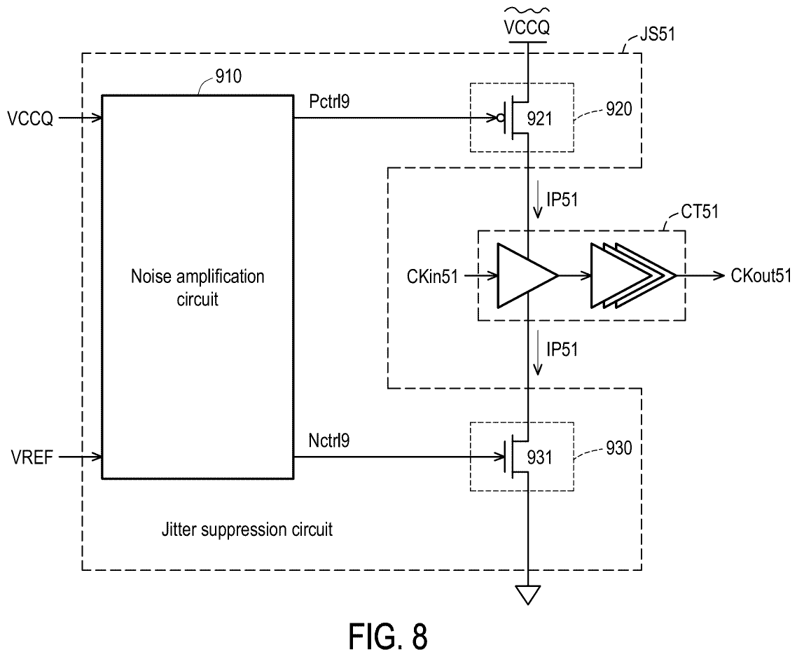

FIG. 8 is a circuit block diagram of the jitter suppression circuit JS51 as illustrated according to an embodiment of the disclosure. The jitter suppression circuit JS51 shown in FIG. 8 may be one of the many embodiment examples of the jitter suppression circuit JS51 shown in FIG. 4. The clock transmission circuit CT51 shown in FIG. 8 may be referenced to the related description of the clock transmission circuit CT51 shown in FIG. 7, so further elaboration is omitted. In the embodiment shown in FIG. 8, the jitter suppression circuit JS51 includes a noise amplification circuit 910, a compensation circuit 920, and a compensation circuit 930. The noise amplification circuit 910 senses the power supply noise of the power voltage VCCQ to generate control signals Pctr19 and Netr19 corresponding to the power supply noise. For example, the noise amplification circuit 910 compares the power voltage VCCQ with a reference voltage VREF. The reference voltage VREF may be a bandgap voltage or another fixed voltage. Based on the difference between the power voltage VCCQ and the reference voltage VREF, the noise amplification circuit 910 generates the control signals Petr19 and Nctr19.

The input end of the compensation circuit 920 receives the power voltage VCCQ. The output end of the compensation circuit 920 is coupled to the power end of the clock transmission circuit CT51 to supply the power current IP51. The control end of the compensation circuit 920 is coupled to the noise amplification circuit 910 to receive the control signal Pctr19. The input end (second end) of the compensation circuit 930 is coupled to the reference end of the clock transmission circuit CT51 to draw the power current IP51. The output end (first end) of the compensation circuit 930 receives a reference voltage (e.g., a ground voltage or another fixed voltage). The control end of the compensation circuit 930 is coupled to the noise amplification circuit 910 to receive the control signal Nctr19. The compensation circuits 920 and 930 adaptively adjust the power current IP51 in response to the control signals Petr19 and Netr19.

In the embodiment shown in FIG. 8, the compensation circuit 920 includes a transistor 921, and the compensation circuit 930 includes a transistor 931. The first end of the transistor 921 (e.g., the source) receives the power voltage VCCQ. The second end of the transistor 921 (e.g., the drain) is coupled to the power end of the clock transmission circuit CT51 to supply the power current IP51. The control end of the transistor 921 (e.g., the gate) is coupled to the noise amplification circuit 910 to receive the control signal Pctr19. The first end of the transistor 931 (e.g., the source) receives the reference voltage (e.g., a ground voltage or another fixed voltage). The second end of the transistor 931 (e.g., the drain) is coupled to the reference end of the clock transmission circuit CT51 to draw the power current IP51. The control end of the transistor 931 (e.g., the gate) is coupled to the noise amplification circuit 910 to receive the control signal Nctr19.

The transistor 921 adaptively adjusts the power current IP51 in response to the control signal Petr19, and the transistor 931 adaptively adjusts the power current IP51 in response to the control signal Nctr19. For example, when the power supply noise of the power voltage VCCQ causes the power voltage VCCQ to increase, the noise amplification circuit 910 adaptively increases the control signal Petr19 and adaptively decreases the control signal Nctr19. As a result, the power current IP51 of the clock transmission circuit CT51 is correspondingly decreased. When the power supply noise of the power voltage VCCQ causes the power voltage VCCQ to decrease, the jitter suppression circuit JS51 adaptively decreases the control signal Pctr19 and adaptively increases the control signal Nctr19. As a result, the power current IP51 of the clock transmission circuit CT51 is correspondingly increased.

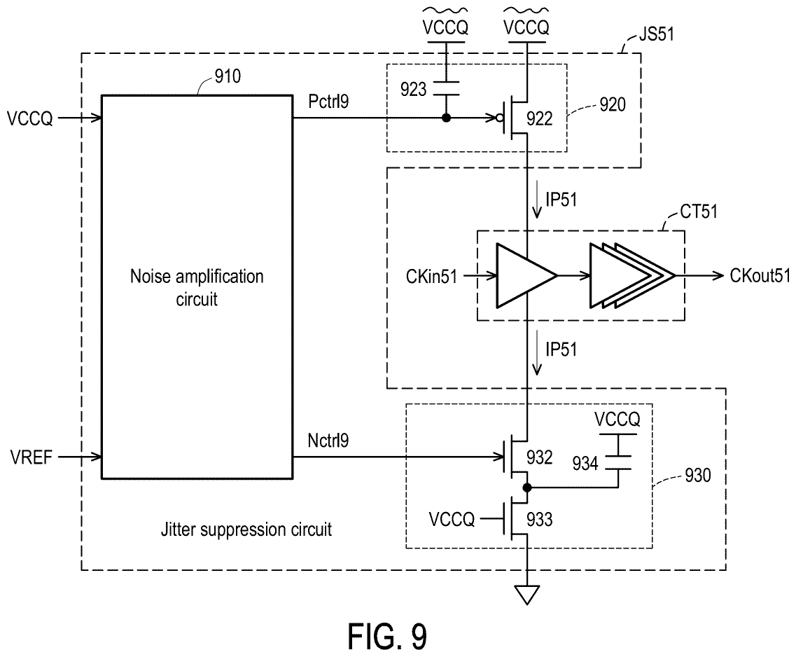

The implementations of the compensation circuits 920 and 930 should not be limited to the example shown in FIG. 8. The compensation circuits 920 and 930 may have different implementations based on practical design and application. For example, FIG. 9 is a circuit block diagram of the compensation circuits 920 and 930 as illustrated according to another embodiment of the disclosure. The jitter suppression circuit JS51 shown in FIG. 9 may be one of the many embodiment examples of the jitter suppression circuit JS51 shown in FIG. 4. The clock transmission circuit CT51 shown in FIG. 9 may be referenced to the related description of the clock transmission circuit CT51 shown in FIG. 7, so further elaboration is omitted.

In the embodiment shown in FIG. 9, the compensation circuit 920 includes a transistor 922 and a capacitor 923. The first end of the transistor 922 (e.g., the source) receives the power voltage VCCQ. The second end of the transistor 922 (e.g., the drain) is coupled to the power end of the clock transmission circuit CT51 to supply the power current IP51. The control end of the transistor 922 (e.g., the gate) is coupled to the noise amplification circuit 910 to receive the control signal Pctr19. The transistor 922 adaptively adjusts the power current IP51 in response to the control signal Pctr19. The first end of the capacitor 923 receives the power voltage VCCQ. The second end of the capacitor 923 is coupled to the control end of the transistor 922.

In the embodiment shown in FIG. 9, the compensation circuit 930 includes a transistor 932, a transistor 933, and a capacitor 934. The control end of the transistor 933 (e.g., the gate) is controlled by the power voltage VCCQ. The first end of the transistor 933 (e.g., the source) receives a reference voltage (e.g., a ground voltage or another fixed voltage). The first end of the transistor 932 (e.g., the source) is coupled to the second end of the transistor 933 (e.g., the drain). The second end of the transistor 932 (e.g., the drain) is coupled to the reference end of the clock transmission circuit CT51 to draw the power current IP51. The control end of the transistor 932 (e.g., the gate) is coupled to the noise amplification circuit 910 to receive the control signal Nctr19. The transistor 932 adaptively adjusts the power current IP51 in response to the control signal Nctr19. The first end of the capacitor 934 receives the power voltage VCCQ. The second end of the capacitor 934 is coupled to the first end of the transistor 932. When the bandwidth of the noise amplification circuit 910 is insufficient, the capacitors 923 and 934 may compensate for the bandwidth.

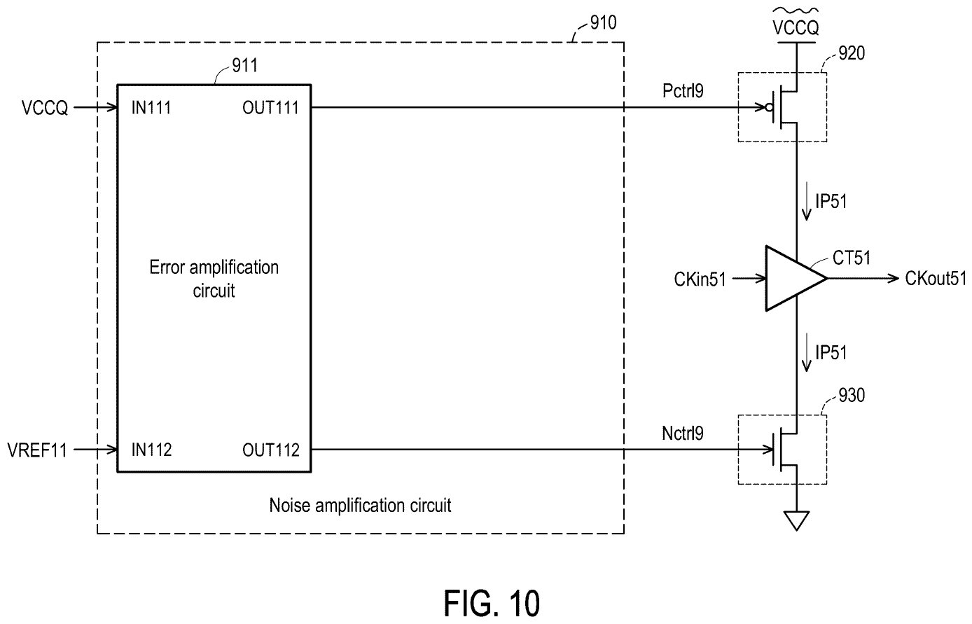

FIG. 10 is a circuit block diagram of the noise amplification circuit 910 as illustrated according to an embodiment of the disclosure. The noise amplification circuit 910 shown in FIG. 10 may be one of the many embodiment examples of the noise amplification circuit 910 shown in FIG. 8 or FIG. 9. The clock transmission circuit CT51 shown in FIG. 10 may be referenced to the related description of the clock transmission circuit CT51 shown in FIG. 4. The compensation circuits 920 and 930 shown in FIG. 10 may be referenced to the related description of the compensation circuits 920 and 930 shown in FIG. 8 or the compensation circuits 920 and 930 shown in FIG. 9.

In the embodiment shown in FIG. 10, the noise amplification circuit 910 includes an error amplification circuit 911. An input end IN111 of the error amplification circuit 911 (e.g., either the non-inverting input or the inverting input) receives the power voltage VCCQ. An input end IN112 of the error amplification circuit 911 (e.g., the other of the non-inverting input or the inverting input) receives a reference voltage VREF11. The level of the reference voltage VREF11 may be determined based on practical design and application. For example, the reference voltage VREF11 may be a bandgap voltage or another fixed voltage. The error amplification circuit 911 compares the power voltage VCCQ with the reference voltage VREF11. Based on the difference between the power voltage VCCQ and the reference voltage VREF11, the error amplification circuit 911 generates control signals Pctr19 and Nctr19. An output end OUT111 of the error amplification circuit 911 is coupled to the control end of the compensation circuit 920 to supply the control signal Pctr19. An output end OUT112 of the error amplification circuit 911 is coupled to the control end of the compensation circuit 930 to supply the control signal Nctr19.

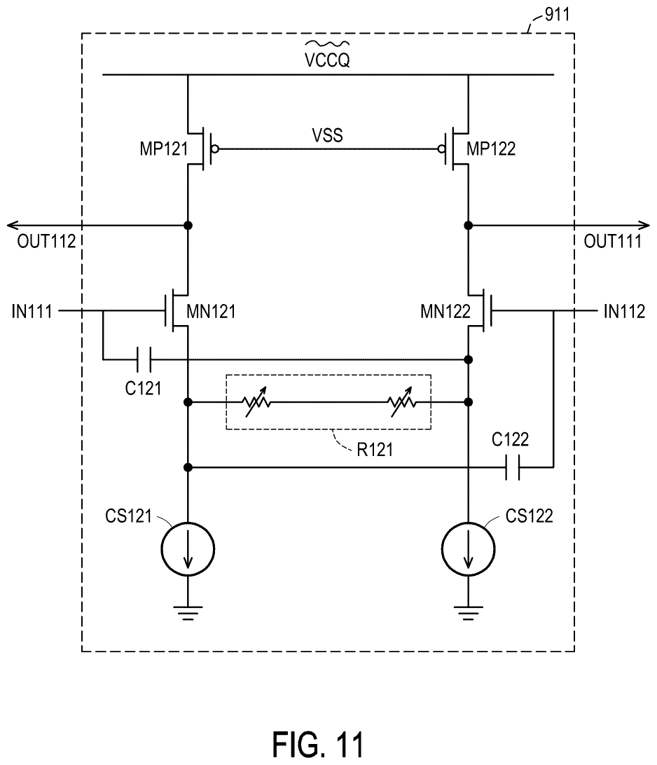

FIG. 11 is a circuit diagram of the error amplification circuit 911 as illustrated according to an embodiment of the disclosure. The error amplification circuit 911 shown in FIG. 11 may be one of the many embodiment examples of the error amplification circuit 911 shown in FIG. 10. The error amplification circuit 911, the input ends IN111 and IN112, and the output ends OUT111 and OUT112 shown in FIG. 11 may be referenced to the related description of FIG. 10. In the embodiment shown in FIG. 11, the error amplification circuit 911 includes a transistor MP121, a transistor MP122, a transistor MN121, a transistor MN122, a resistor R121, a capacitor C121, a capacitor C122, a current source CS121, and a current source CS122. The first end of the transistor MP121 (e.g., the source) and the first end of the transistor MP122 (e.g., the source) receive the power voltage VCCQ. The control end of the transistor MP121 (e.g., the gate) and the control end of the transistor MP122 (e.g., the gate) receive a reference voltage VSS. The level of the reference voltage VSS may be determined based on practical design and application. For example, the reference voltage VSS may be a ground voltage or another fixed voltage.

The second end of the transistor MP121 (e.g., the drain) is coupled to the output end OUT112 of the error amplification circuit 911. The second end of the transistor MP122 (e.g., the drain) is coupled to the output end OUT111 of the error amplification circuit 911. The first end of the transistor MN121 (e.g., the drain) is coupled to the second end of the transistor MP121. The control end of the transistor MN121 (e.g., the gate) is coupled to the input end IN111 of the error amplification circuit 911. The first end of the transistor MN122 (e.g., the drain) is coupled to the second end of the transistor MP122. The control end of the transistor MN122 (e.g., the gate) is coupled to the input end IN112 of the error amplification circuit 911. The first end of the resistor R121 is coupled to the second end of the transistor MN121 (e.g., the source). The second end of the resistor R121 is coupled to the second end of the transistor MN122 (e.g., the source). The first end of the capacitor C121 is coupled to the control end of the transistor MN121. The second end of the capacitor C121 is coupled to the second end of the transistor MN122. The first end of the capacitor C122 is coupled to the control end of the transistor MN122. The second end of the capacitor C122 is coupled to the second end of the transistor MN121. The current source CS121 is coupled to the second end of the transistor MN121. The current source CS122 is coupled to the second end of the transistor MN122.

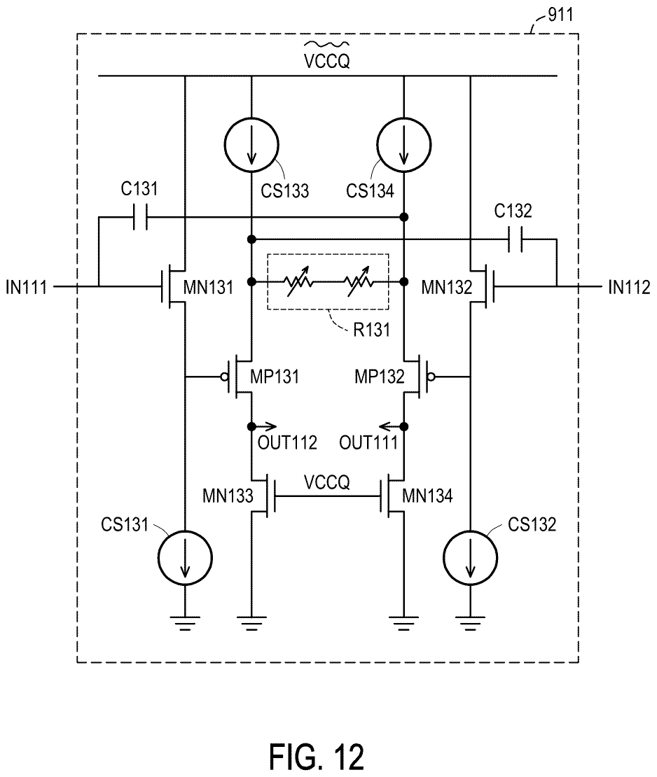

FIG. 12 is a circuit diagram of the error amplification circuit 911 as illustrated according to another embodiment of the disclosure. The error amplification circuit 911 shown in FIG. 12 may be one of the many embodiment examples of the error amplification circuit 911 shown in FIG. 10. The error amplification circuit 911, the input ends IN111 and IN112, and the output ends OUT111 and OUT112 shown in FIG. 12 may be referenced to the related description of FIG. 10. In the embodiment shown in FIG. 12, the error amplification circuit 911 includes a transistor MP131, a transistor MP132, a transistor MN131, a transistor MN132, a transistor MN133, a transistor MN134, a resistor R131, a capacitor C131, a capacitor C132, a current source CS131, a current source CS132, a current source CS133, and a current source CS134. The first end of the transistor MN131 (e.g., the drain) and the first end of the transistor MN132 (e.g., the drain) receive the power voltage VCCQ. The control end of the transistor MN131 (e.g., the gate) is coupled to the input end IN111 of the error amplification circuit 911. The control end of the transistor MN132 (e.g., the gate) is coupled to the input end IN112 of the error amplification circuit 911.

The control end of the transistor MP131 (e.g., the gate) is coupled to the second end of the transistor MN131 (e.g., the source). The first end of the transistor MP131 (e.g., the drain) is coupled to the output end OUT112 of the error amplification circuit 911. The control end of the transistor MP132 (e.g., the gate) is coupled to the second end of the transistor MN132 (e.g., the source). The first end of the transistor MP132 (e.g., the drain) is coupled to the output end OUT111 of the error amplification circuit 911. The first end of the transistor MN133 (e.g., the drain) is coupled to the first end of the transistor MP131. The second end of the transistor MN133 (e.g., the source) receives a reference voltage (e.g., a ground voltage or another fixed voltage). The first end of the transistor MN134 (e.g., the drain) is coupled to the first end of the transistor MP132. The second end of the transistor MN134 (e.g., the source) receives a reference voltage (e.g., a ground voltage or another fixed voltage). The control ends of the transistors MN133 and MN134 (e.g., the gates) receive the power voltage VCCQ.

The first end of the resistor R131 is coupled to the second end of the transistor MP131 (e.g., the source). The second end of the resistor R131 is coupled to the second end of the transistor MP132 (e.g., the source). The first end of the capacitor C131 is coupled to the control end of the transistor MN131. The second end of the capacitor C131 is coupled to the second end of the transistor MP132 (e.g., the source). The first end of the capacitor C132 is coupled to the control end of the transistor MN132. The second end of the capacitor C132 is coupled to the second end of the transistor MP131. The current source CS131 is coupled to the second end of the transistor MN131. The current source CS132 is coupled to the second end of the transistor MN132. The current source CS133 is coupled to the second end of the transistor MP131. The current source CS134 is coupled to the second end of the transistor MP132.

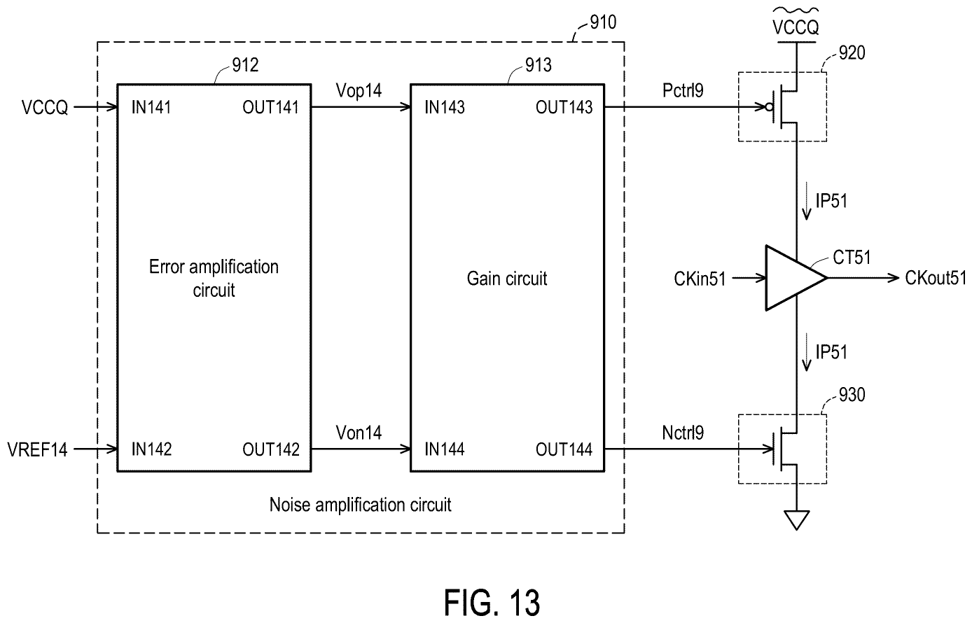

FIG. 13 is a circuit block diagram of the noise amplification circuit 910 as illustrated according to another embodiment of the disclosure. The noise amplification circuit 910 shown in FIG. 13 may be one of the many embodiment examples of the noise amplification circuit 910 shown in FIG. 8 or FIG. 9. The clock transmission circuit CT51 shown in FIG. 13 may be referenced to the related description of the clock transmission circuit CT51 shown in FIG. 4. The compensation circuits 920 and 930 shown in FIG. 13 may be referenced to the related description of the compensation circuits 920 and 930 shown in FIG. 8 or the compensation circuits 920 and 930 shown in FIG. 9.

In the embodiment shown in FIG. 13, the noise amplification circuit 910 includes an error amplification circuit 912 and a gain circuit 913. An input end IN141 of the error amplification circuit 912 (e.g., either the non-inverting input or the inverting input) receives the power voltage VCCQ. An input end IN142 of the error amplification circuit 912 (e.g., the other of the non-inverting input or the inverting input) receives a reference voltage VREF14. The level of the reference voltage VREF14 may be determined based on practical design and application. For example, the reference voltage VREF14 may be a bandgap voltage or another fixed voltage. The error amplification circuit 912 compares the power voltage VCCQ with the reference voltage VREF14. Based on the difference between the power voltage VCCQ and the reference voltage VREF14, the error amplification circuit 912 generates error signals Vop14 and Von14 and provides the error signals Vop14 and Von14 to the gain circuit 913. The error amplification circuit 912, input ends IN141 and IN142, and output ends OUT141 and OUT142 shown in FIG. 13 may be referenced to the related description of the error amplification circuit 911, input ends IN111 and IN112, and output ends OUT111 and OUT112 shown in FIG. 11 or FIG. 12 and inferred accordingly, so further elaboration is omitted.

The input end IN143 of the gain circuit 913 is coupled to the output end OUT141 of the error amplification circuit 912 to receive the error signal Vop14. The input end IN144 of the gain circuit 913 is coupled to the output end OUT142 of the error amplification circuit 912 to receive the error signal Von14. The gain circuit 913 converts the error signals into control signals Pctr19 and Nctr19. An output end OUT143 of the gain circuit 913 is coupled to the control end of the compensation circuit 920 to supply the control signal Pctr19. An output end OUT144 of the gain circuit 913 is coupled to the control end of the compensation circuit 930 to supply the control signal Nctr19. Based on practical design, the gain circuit 913 includes a current-mode logic circuit or another gain circuit. For example, different embodiment examples of the gain circuit 913 will be described below.

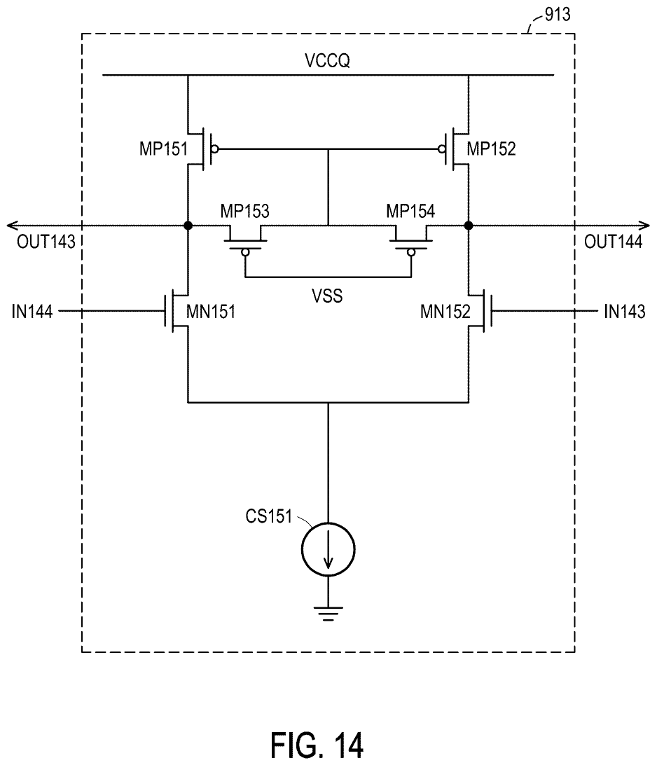

FIG. 14 is a circuit diagram of the gain circuit 913 as illustrated according to an embodiment of the disclosure. The gain circuit 913 shown in FIG. 14 may be one of the many embodiment examples of the gain circuit 913 shown in FIG. 13. The gain circuit 913, input ends IN143 and IN144, and the output ends OUT143 and OUT144 shown in FIG. 14 may be referenced to the related description of FIG. 13. In the embodiment shown in FIG. 14, the gain circuit 913 includes a transistor MP151, a transistor MP152, a transistor MP153, a transistor MP154, a transistor MN151, a transistor MN152, and a current source CS151. The first end of the transistor MP151 (e.g., the source) and the first end of the transistor MP152 (e.g., the source) receive the power voltage VCCQ. The second end of the transistor MP151 (e.g., the drain) is coupled to the output end OUT143 of the gain circuit 913. The second end of the transistor MP152 (e.g., the drain) is coupled to the output end OUT144 of the gain circuit 913. The control end of the transistor MP152 (e.g., the gate) is coupled to the control end of the transistor MP151 (e.g., the gate).

The first end of the transistor MN151 (e.g., the drain) is coupled to the second end of the transistor MP151. The control end of the transistor MN151 (e.g., the gate) is coupled to the input end IN144 of the gain circuit 913. The first end of the transistor MN152 (e.g., the drain) is coupled to the second end of the transistor MP152. The control end of the transistor MN152 (e.g., the gate) is coupled to the input end IN143 of the gain circuit 913. The first end of the transistor MP153 is coupled to the second end of the transistor MP151. The second end of the transistor MP153 is coupled to the control end of the transistors MP151 and MP152. The first end of the transistor MP154 is coupled to the second end of the transistor MP152. The second end of the transistor MP154 is coupled to the control end of the transistors MP151 and MP152. The control ends of the transistors MP153 and MP154 receive the reference voltage VSS. The level of the reference voltage VSS may be determined based on practical design and application. For example, the reference voltage VSS may be a ground voltage or another fixed voltage. The current source CS151 is coupled to the second end (e.g., the source) of the transistor MN151 and the second end (e.g., the source) of the transistor MN152.

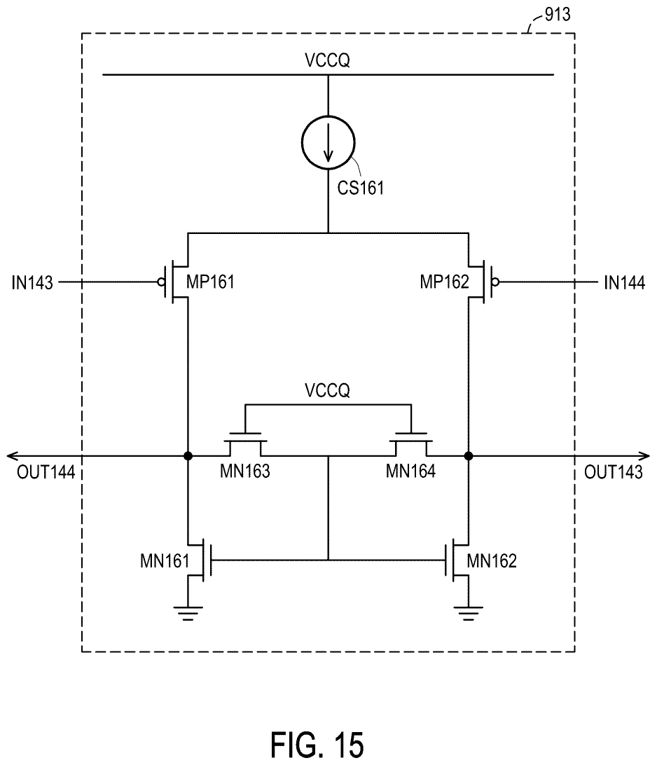

FIG. 15 is a circuit diagram of the gain circuit 913 as illustrated according to another embodiment of the disclosure. The gain circuit 913 shown in FIG. 15 may be one of the many embodiment examples of the gain circuit 913 shown in FIG. 13. The gain circuit 913, input ends IN143 and IN144, and output ends OUT143 and OUT144 shown in FIG. 15 may be referenced to the related description of FIG. 13. In the embodiment shown in FIG. 15, the gain circuit 913 includes a transistor MP161, a transistor MP162, a transistor MN161, a transistor MN162, a transistor MN163, a transistor MN164, and a current source CS161. The first end of the transistor MP161 (e.g., the source) and the first end of the transistor MP162 (e.g., the source) are coupled to the current source CS161. The second end of the transistor MP161 (e.g., the drain) is coupled to the output end OUT144 of the gain circuit 913. The control end of the transistor MP161 (e.g., the gate) is coupled to the input end IN143 of the gain circuit 913. The second end of the transistor MP162 (e.g., the drain) is coupled to the output end OUT143 of the gain circuit 913. The control end of the transistor MP162 (e.g., the gate) is coupled to the input end IN144 of the gain circuit 913.

The first end of the transistor MN161 (e.g., the drain) is coupled to the second end of the transistor MP161. The first end of the transistor MN162 (e.g., the drain) is coupled to the second end of the transistor MP162. The control end of the transistor MN162 (e.g., the gate) is coupled to the control end of the transistor MN161 (e.g., the gate). The second end of the transistor MN161 (e.g., the source) and the second end of the transistor MN162 (e.g., the source) receive a reference voltage (e.g., a ground voltage or another fixed voltage). The first end of the transistor MN163 is coupled to the second end of the transistor MP161. The second end of the transistor MN163 is coupled to the control end of the transistor MN161. The first end of the transistor MN164 is coupled to the second end of the transistor MP162. The second end of the transistor MN164 is coupled to the control end of the transistor MN162. The control ends of the transistors MN163 (e.g., the gate) and MN164 (e.g., the gate) receive the power voltage VCCQ.

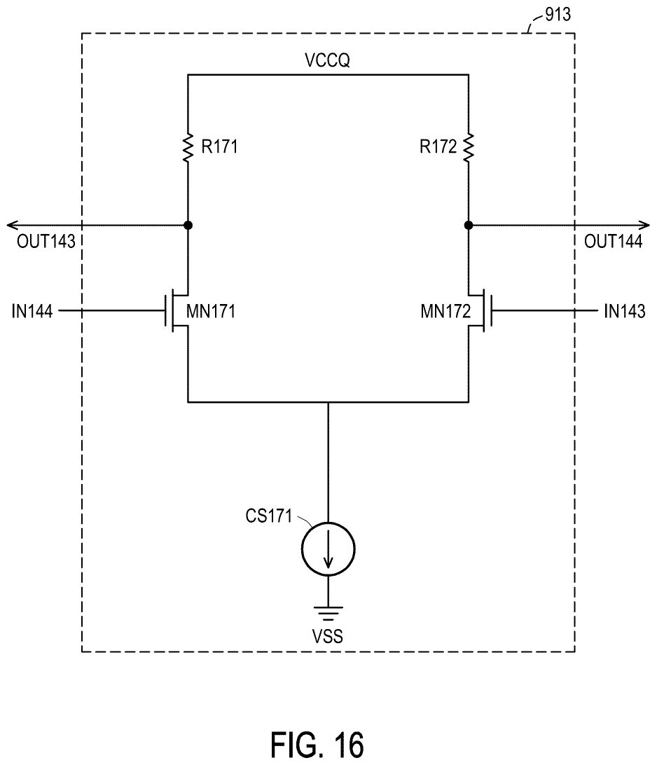

In other embodiments, the gain circuit 913 includes a current-mode logic circuit. For example, FIG. 16 is a circuit diagram of the gain circuit 913 as illustrated according to yet another embodiment of the disclosure. The gain circuit 913 shown in FIG. 16 may be one of the many embodiment examples of the gain circuit 913 shown in FIG. 13. The gain circuit 913, input ends IN143 and IN144, and output ends OUT143 and OUT144 shown in FIG. 16 may be referenced to the related description of FIG. 13. In the embodiment shown in FIG. 16, the gain circuit 913 includes a transistor MN171, a transistor MN172, a resistor R171, a resistor R172, and a current source CS171. The first end of the resistor R171 and the first end of the resistor R172 receive the power voltage VCCQ. The second end of the resistor R171 is coupled to the output end OUT143 of the gain circuit 913. The second end of the resistor R172 is coupled to the output end OUT144 of the gain circuit 913. The first end of the transistor MN171 (e.g., the drain) is coupled to the second end of the resistor R171. The control end of the transistor MN171 (e.g., the gate) is coupled to the input end IN144 of the gain circuit 913. The first end of the transistor MN172 (e.g., the drain) is coupled to the second end of the resistor R172. The control end of the transistor MN172 (e.g., the gate) is coupled to the input end IN143 of the gain circuit 913. The current source CS171 is coupled to the second end of the transistor MN171 (e.g., the source) and the second end of the transistor MN172 (e.g., the source).

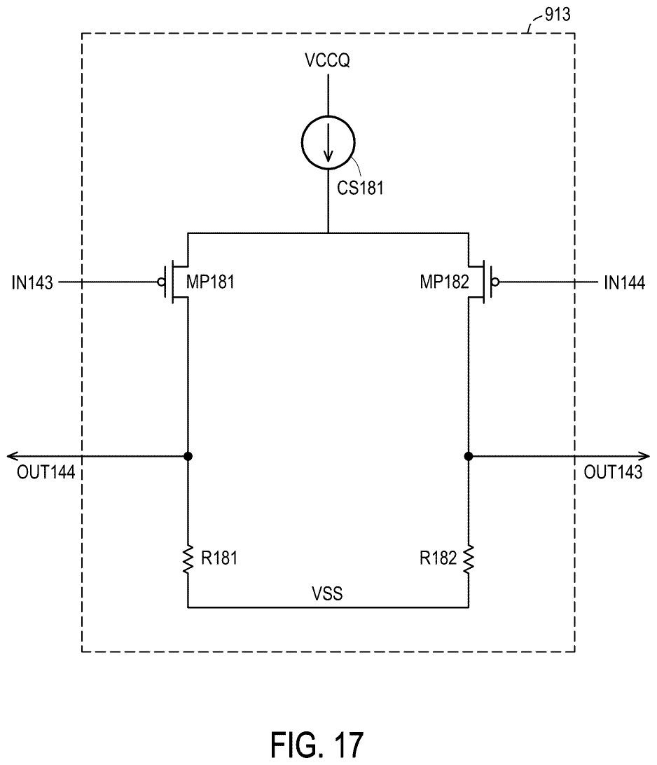

FIG. 17 is a circuit diagram of the gain circuit 913 (current-mode logic circuit) as illustrated according to yet another embodiment of the disclosure. The gain circuit 913 shown in FIG. 17 may be one of the many embodiment examples of the gain circuit 913 shown in FIG. 13. The gain circuit 913, input ends IN143 and IN144, and output ends OUT143 and OUT144 shown in FIG. 17 may be referenced to the related description of FIG. 13. In the embodiment shown in FIG. 17, the gain circuit 913 includes a transistor MP181, a transistor MP182, a resistor R181, a resistor R182, and a current source CS181. The first end of the transistor MP181 (e.g., the source) and the first end of the transistor MP182 (e.g., the source) are coupled to the current source CS181. The second end of the transistor MP181 (e.g., the drain) is coupled to the output end OUT144 of the gain circuit 913. The control end of the transistor MP181 (e.g., the gate) is coupled to the input end IN143 of the gain circuit 913. The second end of the transistor MP182 (e.g., the drain) is coupled to the output end OUT143 of the gain circuit 913. The control end of the transistor MP182 (e.g., the gate) is coupled to the input end IN144 of the gain circuit 913. The first end of the resistor R181 is coupled to the second end of the transistor MP181. The first end of the resistor R182 is coupled to the second end of the transistor MP182. The second end of the resistor R181 and the second end of the resistor R182 receive the reference voltage VSS. The level of the reference voltage VSS may be determined based on practical design and application. For example, the reference voltage VSS may be a ground voltage or another fixed voltage.

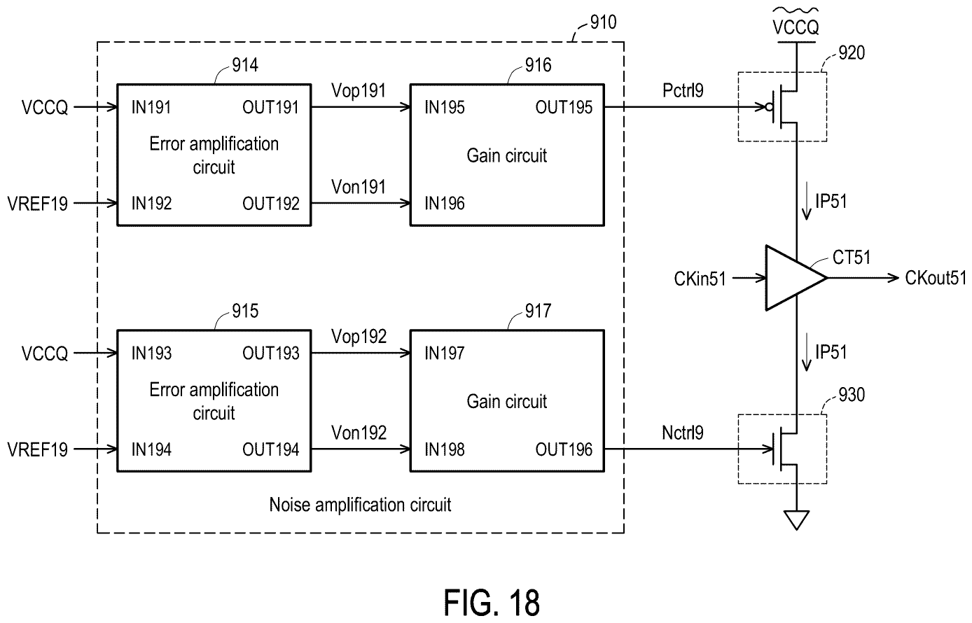

FIG. 18 is a circuit block diagram of the noise amplification circuit 910 as illustrated according to yet another embodiment of the disclosure. The noise amplification circuit 910 shown in FIG. 18 may be one of the many embodiment examples of the noise amplification circuit 910 shown in FIG. 8 or FIG. 9. The clock transmission circuit CT51 shown in FIG. 18 may be referenced to the related description of the clock transmission circuit CT51 shown in FIG. 4. The compensation circuits 920 and 930 shown in FIG. 18 may be referenced to the related description of the compensation circuits 920 and 930 shown in FIG. 8 or the compensation circuits 920 and 930 shown in FIG. 9.

In the embodiment shown in FIG. 18, the noise amplification circuit 910 includes an error amplification circuit 914, an error amplification circuit 915, a gain circuit 916, and a gain circuit 917. An input end IN191 of the error amplification circuit 914 (e.g., either the non-inverting input or the inverting input) receives the power voltage VCCQ, and an input end IN192 of the error amplification circuit 914 (e.g., the other of the non-inverting input or the inverting input) receives a reference voltage VREF19. The level of the reference voltage VREF19 may be determined based on practical design and application. For example, the reference voltage VREF19 may be a bandgap voltage or another fixed voltage. An input end IN193 of the error amplification circuit 915 (e.g., either the non-inverting input or the inverting input) receives the power voltage VCCQ, and an input end IN194 of the error amplification circuit 915 (e.g., the other of the non-inverting input or the inverting input) receives the reference voltage VREF19. The error amplification circuits 914 and 915 may compare the power voltage VCCQ with the reference voltage VREF19. Based on the difference between the power voltage VCCQ and the reference voltage VREF19, the error amplification circuit 914 generates error signals Vop191 and Von191 and provides the error signals Vop191 and Von191 to the gain circuit 916, while the error amplification circuit 915 generates error signals Vop192 and Von192 and provides the error signals Vop192 and Von192 to the gain circuit 917. The error amplification circuit 914, the input ends IN191 and IN192, and output ends OUT191 and OUT192 shown in FIG. 18 may be referenced to the related description of the error amplification circuit 911, input ends IN111 and IN112, and output ends OUT111 and OUT112 shown in FIG. 11 and inferred accordingly. The error amplification circuit 915, the input ends IN193 and IN194, and output ends OUT193 and OUT194 shown in FIG. 18 may be referenced to the related description of the error amplification circuit 911, input ends IN111 and IN112, and output ends OUT111 and OUT112 shown in FIG. 12 and inferred accordingly, so further elaboration is omitted.

An input end IN195 of the gain circuit 916 is coupled to the output end OUT191 of the error amplification circuit 914 to receive the error signal Vop191. An input end IN196 of the gain circuit 916 is coupled to the output end OUT192 of the error amplification circuit 914 to receive the error signal Von191. The gain circuit 916 converts the error signals Vop191 and Von191 into the control signal Pctr19. An output end OUT195 of the gain circuit 916 is coupled to the control end of the compensation circuit 920 to supply the control signal Petr19. An input end IN197 of the gain circuit 917 is coupled to the output end OUT193 of the error amplification circuit 915 to receive the error signal Vop192. An input end IN198 of the gain circuit 917 is coupled to the output end OUT194 of the error amplification circuit 915 to receive the error signal Von192. The gain circuit 917 converts the error signals Vop192 and Von192 into the control signal Nctr19. An output end OUT196 of the gain circuit 917 is coupled to the control end of the compensation circuit 930 to supply the control signal Nctr19. The gain circuit 916, the input ends IN195 and IN196, and the output end OUT195 shown in FIG. 18 may be referenced to the related description of the gain circuit 913, input ends IN143 and IN144, and output end OUT143 shown in FIG. 14 and inferred accordingly. The gain circuit 917, the input ends IN197 and IN198, and the output end OUT196 shown in FIG. 18 may be referenced to the related description of the gain circuit 913, input ends IN143 and IN144, and output end OUT144 shown in FIG. 15 and inferred accordingly, so further elaboration is omitted.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

1. A clock transmission device comprising:
a clock transmission circuit generating at least one output clock based on an input clock; and
a jitter suppression circuit supplying a power current to the clock transmission circuit based on a power voltage,
wherein the jitter suppression circuit adaptively adjusts the power current in response to a power supply noise of the power voltage to suppress a power noise induced jitter of the at least one output clock,
wherein the jitter suppression circuit comprises:
a noise amplification circuit sensing the power supply noise of the power voltage to generate a first control signal corresponding to the power supply noise; and
a first compensation circuit, wherein an input end of the first compensation circuit receives the power voltage, an output end of the first compensation circuit is coupled to a power end of the clock transmission circuit to supply the power current, a control end of the first compensation circuit is coupled to the noise amplification circuit to receive the first control signal, and the first compensation circuit adaptively adjusts the power current in response to the first control signal,
wherein the first compensation circuit comprises:
a transistor, wherein a first end of the transistor receives the power voltage, a second end of the transistor is coupled to the power end of the clock transmission circuit to supply the power current, a control end of the transistor is coupled to the noise amplification circuit to receive the first control signal, and the transistor adaptively adjusts the power current in response to the first control signal; and
a capacitor, wherein a first end of the capacitor receives the power voltage, and a second end of the capacitor is coupled to the control end of the transistor.

2. The clock transmission device according to claim 1, wherein the clock transmission circuit comprises:
a gain circuit generating a gained clock by gaining the input clock, wherein the jitter suppression circuit supplies the power current to the gain circuit, and the jitter suppression circuit senses the power supply noise of the power voltage to adaptively adjust the power current, so as to suppress a power noise induced jitter of the gained clock; and
a clock tree circuit coupled to an output end of the gain circuit to receive the gained clock, wherein the clock tree circuit generates the at least one output clock based on the gained clock.

3. (canceled)

4. (canceled)

5. (canceled)

6. The clock transmission device according to claim 1, wherein the noise amplification circuit comprises:
an error amplification circuit, wherein a first input end of the error amplification circuit receives the power voltage, a second input end of the error amplification circuit receives a first reference voltage, the error amplification circuit compares the power voltage with the first reference voltage to generate the first control signal, and a first output end of the error amplification circuit is coupled to the control end of the first compensation circuit to supply the first control signal.

7. The clock transmission device according to claim 6, wherein the first reference voltage is a bandgap voltage.

8. The clock transmission device according to claim 6, wherein the error amplification circuit comprises:
a first transistor, wherein a first end of the first transistor receives the power voltage, a second end of the first transistor is coupled to a second output end of the error amplification circuit, and a control end of the first transistor receives a second reference voltage;
a second transistor, wherein a first end of the second transistor receives the power voltage, a second end of the second transistor is coupled to the first output end of the error amplification circuit, and a control end of the second transistor receives the second reference voltage;
a third transistor, wherein a first end of the third transistor is coupled to the second end of the first transistor, and a control end of the third transistor is coupled to the first input end of the error amplification circuit;
a fourth transistor, wherein a first end of the fourth transistor is coupled to the second end of the second transistor, and a control end of the fourth transistor is coupled to the second input end of the error amplification circuit;
a resistor, wherein a first end of the resistor is coupled to a second end of the third transistor, and a second end of the resistor is coupled to a second end of the fourth transistor;
a first capacitor, wherein a first end of the first capacitor is coupled to the control end of the third transistor, and a second end of the first capacitor is coupled to the second end of the fourth transistor;
a second capacitor, wherein a first end of the second capacitor is coupled to the control end of the fourth transistor, and a second end of the second capacitor is coupled to the second end of the third transistor;
a first current source coupled to the second end of the third transistor; and
a second current source coupled to the second end of the fourth transistor.

9. The clock transmission device according to claim 6, wherein the error amplification circuit comprises:
a first transistor, wherein a first end of the first transistor receives the power voltage, and a control end of the first transistor is coupled to the first input end of the error amplification circuit;
a second transistor, wherein a first end of the second transistor receives the power voltage, and a control end of the second transistor is coupled to the second input end of the error amplification circuit;
a third transistor, wherein a control end of the third transistor is coupled to a second end of the first transistor, and a first end of the third transistor is coupled to a second output end of the error amplification circuit;
a fourth transistor, wherein a control end of the fourth transistor is coupled to a second end of the second transistor, and a first end of the fourth transistor is coupled to the first output end of the error amplification circuit;
a fifth transistor, wherein a first end of the fifth transistor is coupled to the first end of the third transistor, a second end of the fifth transistor receives a second reference voltage, and a control end of the fifth transistor receives the power voltage;
a sixth transistor, wherein a first end of the sixth transistor is coupled to the first end of the fourth transistor, a second end of the sixth transistor receives the second reference voltage, and a control end of the sixth transistor receives the power voltage;
a resistor, wherein a first end of the resistor is coupled to a second end of the third transistor, and a second end of the resistor is coupled to a second end of the fourth transistor;
a first capacitor, wherein a first end of the first capacitor is coupled to the control end of the first transistor, and a second end of the first capacitor is coupled to the second end of the fourth transistor;
a second capacitor, wherein a first end of the second capacitor is coupled to the control end of the second transistor, and a second end of the second capacitor is coupled to the second end of the third transistor;
a first current source coupled to the second end of the first transistor;
a second current source coupled to the second end of the second transistor;
a third current source coupled to the second end of the third transistor; and
a fourth current source coupled to the second end of the fourth transistor.

10. A clock transmission device comprising:
a clock transmission circuit generating at least one output clock based on an input clock; and
a jitter suppression circuit supplying a power current to the clock transmission circuit based on a power voltage,
wherein the jitter suppression circuit adaptively adjusts the power current in response to a power supply noise of the power voltage to suppress a power noise induced jitter of the at least one output clock,
wherein the jitter suppression circuit comprises:
a noise amplification circuit sensing the power supply noise of the power voltage to generate a first control signal corresponding to the power supply noise; and
a first compensation circuit, wherein an input end of the first compensation circuit receives the power voltage, an output end of the first compensation circuit is coupled to a power end of the clock transmission circuit to supply the power current, a control end of the first compensation circuit is coupled to the noise amplification circuit to receive the first control signal, and the first compensation circuit adaptively adjusts the power current in response to the first control signal;
wherein the noise amplification circuit comprises:
an error amplification circuit, wherein a first input end of the error amplification circuit receives the power voltage, a second input end of the error amplification circuit receives a first reference voltage, and the error amplification circuit compares the power voltage with the first reference voltage to generate an error signal; and
a gain circuit, wherein a first input end of the gain circuit is coupled to a first output end of the error amplification circuit, a second input end of the gain circuit is coupled to a second output end of the error amplification circuit, the gain circuit converts the error signal into the first control signal, and a first output end of the gain circuit is coupled to the control end of the first compensation circuit to supply the first control signal.

11. The clock transmission device according to claim 10, wherein the gain circuit comprises:
a first transistor, wherein a first end of the first transistor receives the power voltage, and a second end of the first transistor is coupled to the first output end of the gain circuit;
a second transistor, wherein a first end of the second transistor receives the power voltage, a second end of the second transistor is coupled to a second output end of the gain circuit, and a control end of the second transistor is coupled to a control end of the first transistor;
a third transistor, wherein a first end of the third transistor is coupled to the second end of the first transistor, and a control end of the third transistor is coupled to the second input end of the gain circuit;
a fourth transistor, wherein a first end of the fourth transistor is coupled to the second end of the second transistor, and a control end of the fourth transistor is coupled to the first input end of the gain circuit;
a fifth transistor, wherein a first end of the fifth transistor is coupled to the second end of the first transistor, a second end of the fifth transistor is coupled to the control end of the first transistor, and a control end of the fifth transistor receives a second reference voltage;
a sixth transistor, wherein a first end of the sixth transistor is coupled to the second end of the second transistor, a second end of the sixth transistor is coupled to the control end of the second transistor, and a control end of the sixth transistor receives the second reference voltage; and
a current source coupled to a second end of the third transistor and a second end of the fourth transistor.

12. The clock transmission device according to claim 10, wherein the gain circuit comprises:
a current source;
a first transistor, wherein a first end of the first transistor is coupled to the current source, a second end of the first transistor is coupled to a second output end of the gain circuit, and a control end of the first transistor is coupled to the first input end of the gain circuit;
a second transistor, wherein a first end of the second transistor is coupled to the current source, a second end of the second transistor is coupled to the first output end of the gain circuit, and a control end of the second transistor is coupled to the second input end of the gain circuit;
a third transistor, wherein a first end of the third transistor is coupled to the second end of the first transistor, and a second end of the third transistor receives a second reference voltage;
a fourth transistor, wherein a first end of the fourth transistor is coupled to the second end of the second transistor, a second end of the fourth transistor receives the second reference voltage, and a control end of the fourth transistor is coupled to a control end of the third transistor;
a fifth transistor, wherein a first end of the fifth transistor is coupled to the second end of the first transistor, a second end of the fifth transistor is coupled to the control end of the third transistor, and a control end of the fifth transistor receives the power voltage; and
a sixth transistor, wherein a first end of the sixth transistor is coupled to the second end of the second transistor, a second end of the sixth transistor is coupled to the control end of the fourth transistor, and a control end of the sixth transistor receives the power voltage.

13. The clock transmission device according to claim 10, wherein the gain circuit comprises a current mode logic circuit.

14. The clock transmission device according to claim 13, wherein the current mode logic circuit comprises:
a first resistor, wherein a first end of the first resistor receives the power voltage, and a second end of the first resistor is coupled to the first output end of the gain circuit;
a second resistor, wherein a first end of the second resistor receives the power voltage, and a second end of the second resistor is coupled to a second output end of the gain circuit;
a first transistor, wherein a first end of the first transistor is coupled to the second end of the first resistor, and a control end of the first transistor is coupled to the second input end of the gain circuit;
a second transistor, wherein a first end of the second transistor is coupled to the second end of the second resistor, and a control end of the second transistor is coupled to the first input end of the gain circuit; and
a current source coupled to a second end of the first transistor and a second end of the second transistor.

15. The clock transmission device according to claim 13, wherein the current mode logic circuit comprises:
a current source;
a first transistor, wherein a first end of the first transistor is coupled to the current source, a second end of the first transistor is coupled to a second output end of the gain circuit, and a control end of the first transistor is coupled to the first input end of the gain circuit;
a second transistor, wherein a first end of the second transistor is coupled to the current source, a second end of the second transistor is coupled to the first output end of the gain circuit, and a control end of the second transistor is coupled to the second input end of the gain circuit;
a first resistor, wherein a first end of the first resistor is coupled to the second end of the first transistor, and a second end of the first resistor receives a second reference voltage; and
a second resistor, wherein a first end of the second resistor is coupled to the second end of the second transistor, and a second end of the second resistor receives the second reference voltage.

16. The clock transmission device according to claim 1, wherein the noise amplification circuit comprises:
a first error amplification circuit, wherein a first input end of the first error amplification circuit receives the power voltage, a second input end of the first error amplification circuit receives a first reference voltage, and the first error amplification circuit compares the power voltage with the first reference voltage to generate a first error signal;
a first gain circuit, wherein a first input end of the first gain circuit is coupled to a first output end of the first error amplification circuit, a second input end of the first gain circuit is coupled to a second output end of the first error amplification circuit, the first gain circuit converts the first error signal into the first control signal, and an output end of the first gain circuit is coupled to the control end of the first compensation circuit to supply the first control signal;
a second error amplification circuit, wherein a first input end of the second error amplification circuit receives the power voltage, a second input end of the second error amplification circuit receives the first reference voltage, and the second error amplification circuit compares the power voltage with the first reference voltage to generate a second error signal; and
a second gain circuit, wherein a first input end of the second gain circuit is coupled to a first output end of the second error amplification circuit, a second input end of the second gain circuit is coupled to a second output end of the second error amplification circuit, the second gain circuit converts the second error signal into a second control signal, an output end of the second gain circuit is coupled to a control end of a second compensation circuit of the jitter suppression circuit to supply the second control signal, a first end of the second compensation circuit receives a second reference voltage, and a second end of the second compensation circuit is coupled to a reference end of the clock transmission circuit.

17. The clock transmission device according to claim 1, wherein the jitter suppression circuit further comprises:
a second compensation circuit, wherein a first end of the second compensation circuit receives a reference voltage, a second end of the second compensation circuit is coupled to a reference end of the clock transmission circuit, and a control end of the second compensation circuit is coupled to the noise amplification circuit to receive a second control signal.

18. The clock transmission device according to claim 17, wherein the second compensation circuit comprises:
a transistor, wherein a first end of the transistor receives the reference voltage, a second end of the transistor is coupled to the reference end of the clock transmission circuit, and a control end of the transistor is coupled to the noise amplification circuit to receive the second control signal.

19. The clock transmission device according to claim 17, wherein the second compensation circuit comprises:
a first transistor, wherein a first end of the first transistor receives the reference voltage, and a control end of the first transistor receives the power voltage;
a second transistor, wherein a first end of the second transistor is coupled to a second end of the first transistor, a second end of the second transistor is coupled to the reference end of the clock transmission circuit, and a control end of the second transistor is coupled to the noise amplification circuit to receive the second control signal; and
a capacitor, wherein a first end of the capacitor receives the power voltage, and a second end of the capacitor is coupled to the first end of the second transistor.

20. An operation method of a clock transmission device, comprising:
generating at least one output clock by a clock transmission circuit of the clock transmission device based on an input clock;
supplying a power current to the clock transmission circuit by a jitter suppression circuit of the clock transmission device based on a power voltage;
adaptively adjusting the power current by the jitter suppression circuit in response to a power supply noise of the power voltage, so as to suppress a power noise induced jitter of the at least one output clock;
sensing the power supply noise of the power voltage to generate a first control signal corresponding to the power supply noise by a noise amplification circuit of the jitter suppression circuit:
adaptively adjusting the power current in response to the first control signal by a first compensation circuit of the jitter suppression circuit, wherein an input end of the first compensation circuit receives the power voltage, an output end of the first compensation circuit is coupled to a power end of the clock transmission circuit to supply the power current, and a control end of the first compensation circuit is coupled to the noise amplification circuit to receive the first control signal;
comparing the power voltage with a first reference voltage to generate an error signal by an error amplification circuit of the noise amplification circuit, wherein a first input end of the error amplification circuit receives the power voltage, and a second input end of the error amplification circuit receives the first reference voltage; and
converting the error signal into the first control signal by a gain circuit of the noise amplification circuit, wherein a first input end of the gain circuit is coupled to a first output end of the error amplification circuit, a second input end of the gain circuit is coupled to a second output end of the error amplification circuit, and a first output end of the gain circuit is coupled to the control end of the first compensation circuit to supply the first control signal.

21. The operation method according to claim 20, further comprising:
supplying the power current to a gain circuit of the clock transmission circuit by the jitter suppression circuit;
gaining an input clock to generate a gained clock by the gain circuit;
sensing the power supply noise of the power voltage to adaptively adjust the power current by the jitter suppression circuit, so as to suppress a power noise induced jitter of the gained clock; and
generating the at least one output clock by a clock tree circuit of the clock transmission circuit based on the gained clock, wherein the clock tree circuit is coupled to the gain circuit to receive the gained clock.

22. (canceled)

23. (canceled)

24. The operation method according to claim 20, wherein the first reference voltage is a bandgap voltage.

25. (canceled)

26. (canceled)
